(19) United States
(12) Patent Application Publication
(10) Pub. No.: US 2010/0043867 A1
(43) Pub. Date: Feb. 25, 2010

(54) Solar and thermal energy to electricity conversion

(76) Inventor: Gang Grant Peng, Fremont, CA (US)

Correspondence Address: GANG GRANT PENG, 32 MISSION CIELO AVE, FREMONT, CA, 94539, US

(21) Appl. No.: 12/229,152

(22) Filed: Aug. 19, 2008

(51) Int. Cl. H01L 31/042

(52) U.S. Cl. 136/248

(57) ABSTRACT

The present invention discloses a new apparatus and method for converting solar energy or thermal energy to electricity, requiring simple design and production. The present invention will apply the work from the solar or thermal energy to the variable capacitors that convert into electric energy. The output energy from the present invention will be ready for grid connection.

### REFERENCES SITED

### US PATENT DOCUMENTS

| | | | |
|---|---|---|---|
| 7,405,013 | Jul. 29, 2008 | Yang et al. | 429/13 |
| 7,340,898 | Mar. 11, 2008 | Miller. | 60/641.8 |
| 6,898,450 | May 24, 2005 | Eden et al. | 505/210 |
| 6,326,541 | Dec. 4, 2001 | Goheen. | 136/253 |
| 5,644,184 | Jul. 1, 1997 | Kucherov. | 310/306 |
| 4,425,540 | Jan. 10, 1984 | Olsen. | 322/2 A |
| 4,213,797 | Jul. 22, 1980 | Sher | 136/89 |
| 4,151,409 | Apr. 24, 1979 | O'Hare. | 250/212 |
| 2,981,777 | Apr. 21, 1961 | Reynolds. | |

### BACKGROUND OF THE INVENTION

(1) Field of the Invention

The present invention relates to the convertion of solar energy into electric energy, particularly to a conversion apparatus and method including a solar energy collector, a thermal (or from solar energy)-mechanical energy conversion, and a mechanical-electrical energy conversion.

(2) Prior Art

There are following major technologies for utilizing solar energy:
a) converting solar energy into electricity—the photovoltaic (PV). The photovoltaic is based on the principle of a photon generating a free electron and a hole in semiconductor material and on the semiconductor processing technology. But the manufactory and material cost are high. The example of such photovoltaic devices is U.S. Pat. No. 2,981,777.
b) Converting solar energy into heat. The solar thermal is based on the principle that photons will generate heat when interacting with material atoms or molecules. This technology is mainly for thermal utilization of the solar energy, e.g. heating water, and solar farm utilizations, U.S. Pat. No. 7,340,898.
c) Converting solar energy into heat which excites the thermal ions of material of the emitter (Solar Thermionic Energy Convert), U.S. Pat. No. 6,326,541.
d) Using a capacitor to convert solar thermal energy to electricity is well known. The common way to directly generate electricity is by shining light on a capacitor, which changes the capacitance during the radiation by using the photon sensitive or thermal sensitive dielectric material inside the capacitor. During the temperature change or exposure to light, the capacitance of the dielectric material changes, therefore the energy stored in the capacitor changes,

$$\begin{matrix}C = \frac{Q}{V} = \frac{{κɛ}_{0} A}{d} & ( 1 ) \\ U = \frac{1}{2} {CV}^{2} & ( 2 )\end{matrix}$$

where C is the capacitance, Q is the charge, V is the voltage, k is the dielectric constant of the material inside the capacitor, ε₀ is the permittivity constant, A is the area of the capacitor, d is the distance between the two plates of the capacitor, U is the energy stored in the capacitor, V is the voltage of the capacitor. The different capacitance results in either an electric charge or an electric potential change. The examples are U.S. Pat. No. 4,151,409. This type of solar energy conversion has the advantage of no mechanical motion. However, the light sensitive material or the thermal sensitive material is more problematic for its stability, charge uniformity, and durability of the operation condition of the normal power grid. For example, the pyroelectric power conversion uses temperature dependent capacitances with pulsing heat flow through the stacked capacitors, U.S. Pat. No. 5,644,184.
e) Converting the photon to electricity is by using photocapacitivity, which is mainly used for photon imaging and light detection, especially for very low photon flux condition, U.S. Pat. No. 4,213,797.
f) Converting the thermal energy into electricity by thermoelectric means, e.g. U.S. Pat. No. 7,405,013. It is based on the thermal electrons generated at the hot end and flow to the cooler end. The need for exotic material for the thermoelectric device makes it expensive and environmentally unfriendly.
g) Changing the gap of a capacitor will generate electricity as well because it increases the system energy when the capacitance has reduced. Eden et al in U.S. Pat. No. 6,898,450 used piezoelectric material (PZT) to vary the gap between two electrode plates in the range of Δd/d=1.0 to 1.5. It was invented for the tunable filter for frequency modulation usage with limited power output.

Currently, the popular solar—electricity conversion technologies need to use a power conversion box to increase the voltage of the electricity generated by the solar energy conversion device, such as a PV panel, to match to that of the grid before delivering the electricity. This adds costs to the solar energy application as well as lower the photo-electricity conversion efficiency.

As described above, a means of directly converting the solar energy to electricity at the grid voltage with reasonable efficiency will be more suitable for solar energy or thermal energy conversion due to its economic advantage.

### SUMMARY OF THE INVENTION

The present invention provides a means of converting the solar energy directly into electricity at the grid voltage. The primary object of the present invention is to establish an apparatus and method to convert the solar energy to electricity directly by a different approach rather than by the existing technologies. The first embodiment coverts the solar energy collected by a parabolic trough to mechanical energy by elongating a metallic bar when heated. The elongated metallic bar will either increase the gap between two plates of a capacitor which results in more energy stored in the capacitor or decrease the gap which results in less energy stored in the capacitor. When the capacitor is connected to a circuit or a grid, the extra electric energy in the capacitor will be transferred out of the capacitor into the circuit or grid.

The second objective of the present invention is to have a pair of variable capacitors or a variable capacitor array that will be used to generate electricity by changing the gap of a capacitor. When one capacitor's gap increases, its paired capacitor decreases which leads it to its initial stage. Therefore, one capacitor will have additional energy during heating and the other capacitor will store additional energy during cooling down. The pair of variable capacitors has a two fold function, a) to convert the thermal energy whether the temperature is changing either from cold to hot or from hot to cold; b) recover the variable capacitor to its initial stage and charge it with the initial energy.

The third objective of the present invention is to establish an apparatus and method to enable a continuous electricity generation cycle. Arranging an array of variable capacitors in special mechanical and electrical ways will make continuous electricity generation. When one of the capacitors is increasing its energy for electricity generation, another one is backing to its initial stage for the next electricity generation circle. Running cold media through the metallic thermal collector provides the cooling power to bring part of the system, collector and certain variable capacitors, back to its initial stage. The array of variable capacitors can be setup in such a way that certain variable capacitors generate electricity during heat up while others during cool down. Also the array of variable capacitors can be arranged in such a way that its output electricity will have the same voltage as that of the grid which it connects to.

The fourth objective of the present invention is an universal electricity conversion for generating electricity with other thermal sources, e.g. the geothermal.

Overall, the present invention will enable solar energy conversion to electricity through a means of thermal mechanical and electrical storage instead of photovoltaic or solar thermal types of conversions. The present invention has the advantages of simplicity of design, low cost production, and less dependency on direct sunlight.

To achieve the first object, the present invention will couple the solar energy with a variable capacitor through a pair of materials with different thermal properties. The solar energy is collected by a parabolic trough and converted into mechanical motion which changes the capacitance of the variable capacitor.

To achieve the second object, the present invention will apply the mechanical motion converted from the solar energy to a pair of variable capacitors. The pair of capacitors are connected in such a way that one capacitor will be energized and another capacitor will set back to initial stage regardless of the direction of the mechanical motion. This provides a means of continuously operating the solar energy - electricity conversion.

To achieve the third object, the present invention will use multiple variable capacitors and they will be arranged in certain ways to max the power output and make the out power condition match with the grid requirement. A cooling source is used to continuously operate the electricity generation circle.

To achieve the fourth object, the present invention will use the other thermal source replacing the solar source.

The present invention has the following advantages.
1. It provides a new approach to convert the solar energy to electricity with higher efficiency and simpler processing.
2. It works when there is no direct sun light.
3. It works when there is a temperature difference between the environment and cooling source.
4. It provides a technology that can be universally used for thermal - electricity conversion regardless of whether the thermal source is solar, geo or an ocean wave. The present invention can be used as long as there is a temperature difference between the thermal source and the cooling source.

Further objects and advantages of the present invention will become apparent from a consideration of the description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow when read in conjunction with the accompanying drawings.

FIG. 1. is a sectional view of the apparatus for a variable capacitor and its circuit diagram in the present invention.

FIG. 2a. is a sectional view of the apparatus of a pair of variable capacitors.

FIG. 2b. is a circuit diagram of the apparatus of a pair of variable capacitors.

FIG. 3. is a sectional view of the apparatus for solar energy conversion.

FIG. 4. is a sectional view of the apparatus for thermal energy conversion.

### DETAILED DESCRIPTION OF THE INVENTION

While embodiments of the present invention will be described below, those skilled in the art will recognize that other assemblies, configurations, and processes are capable of implementing the principles of the present invention. Thus the following description is illustrative only and not limiting.

Reference is specifically made to the drawings wherein like numbers are used to designate like members throughout.

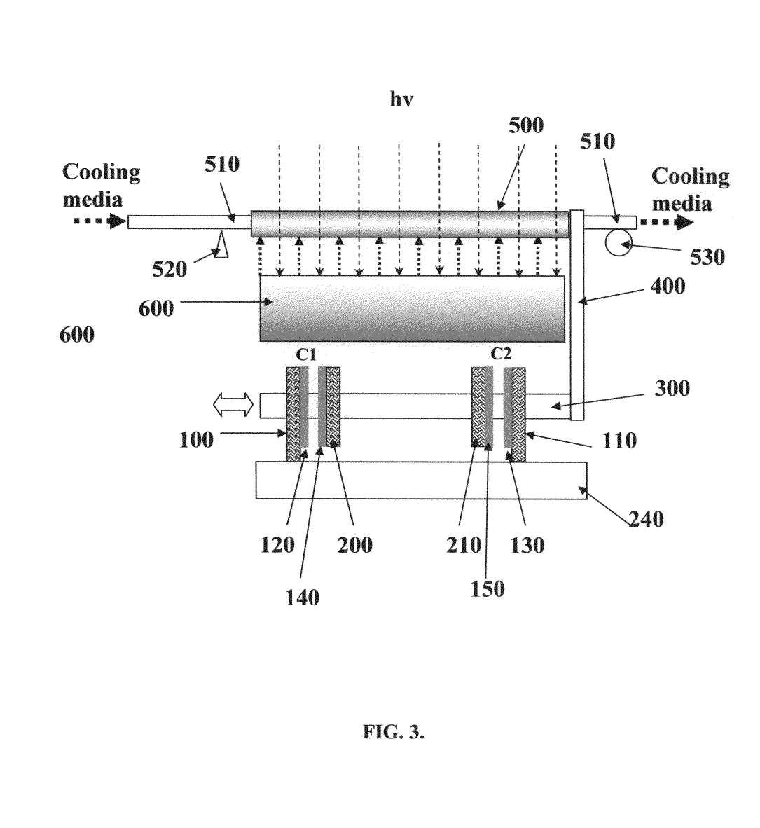

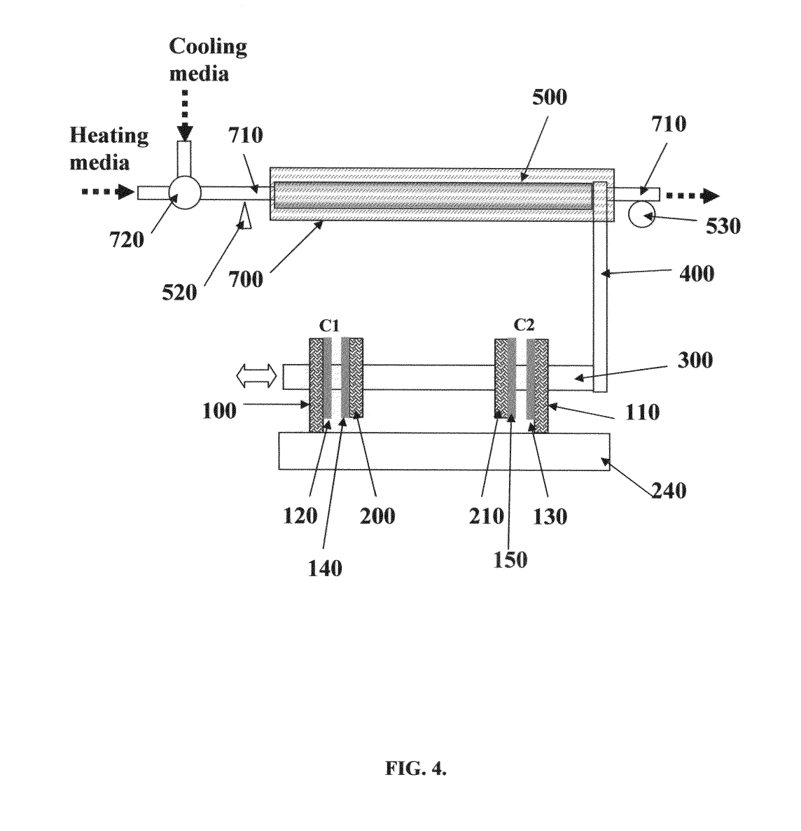

Note the following:
(1) The dimensions of all of drawings are not to scale.
(2) A pair of variable capacitors as embodiments of the present invention is illustrated in FIG. 3 and FIG. 4. However the same or multiple pairs of variable capacitors is applicable to energy conversion apparatuses.
(3) The variable capacitor may be metallic plates or semiconductor plates or insulator plates with metallic coatings or other materials.
(4) The variable capacitor may fill the gap with air or other materials.
(5) The variable capacitor may have a dielectric slab in its gap.

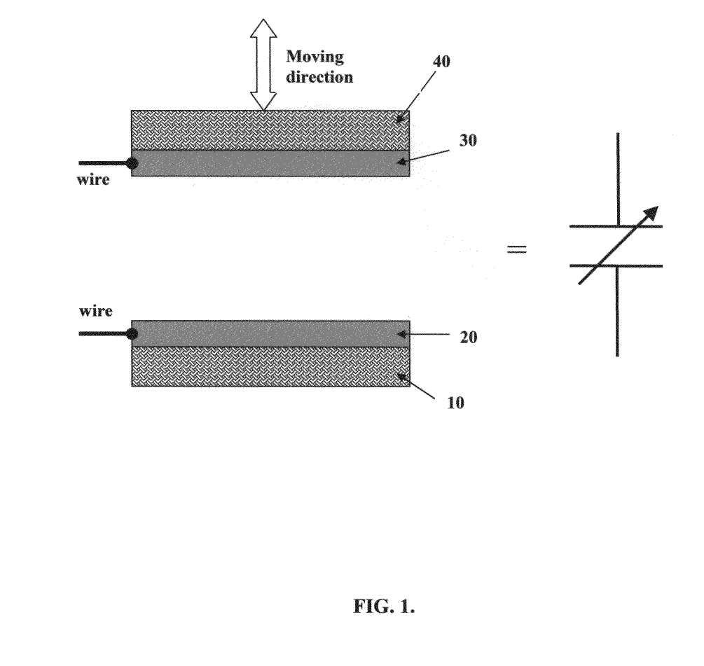

The first embodiment of the present invention is illustrated in FIG. 1. which shows the apparatus of a parallel-plates-type of variable capacitor. The plates, 10 and 40, can be made of either metal or non metal materials. The films, 20 and 30, will be made of conductive material and they may be the same or different. When the gap between these plates change, the energy stored in its electric field change accordingly. The energy storage for this type of variable capacitor can be described as:

$${U}_{f} = {U}_{0} \cdot ( \frac{{d}_{f}}{{d}_{0}} ) \qquad ( 3 )$$

where U_{f} and U₀ are the final and initial energy stored in the capacitor respectively, and d_{f} and d₀ are the final and initial gaps respectively. The capacitor is charged at its initial stage—gap, and then external work increases the gap, which results in higher energy stored in the capacitor. The larger the gap, the higher the energy stored in the capacitor because of weaker static interactions between the charges on the two plates.

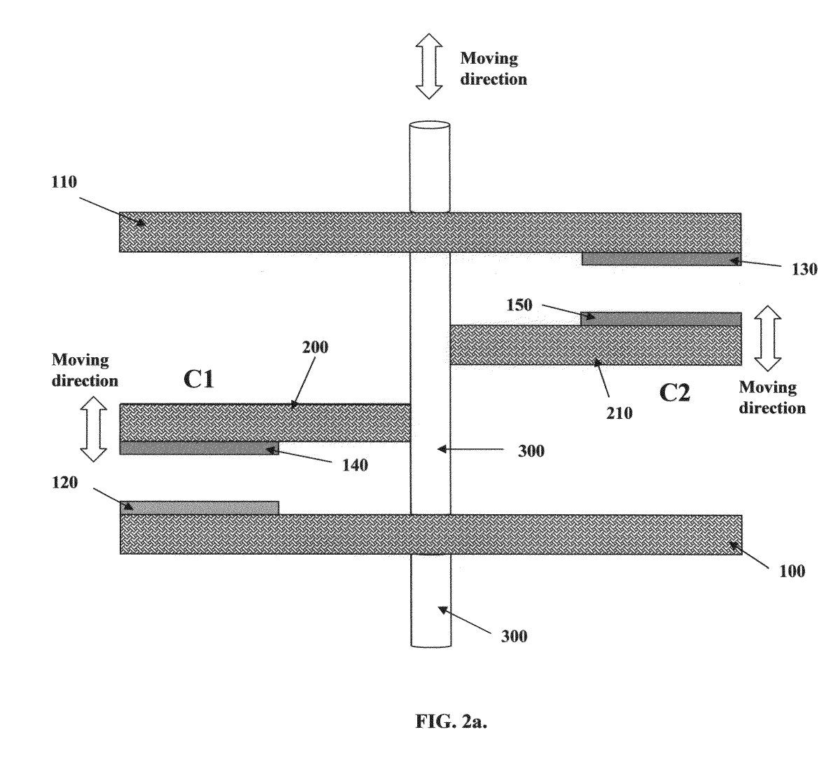

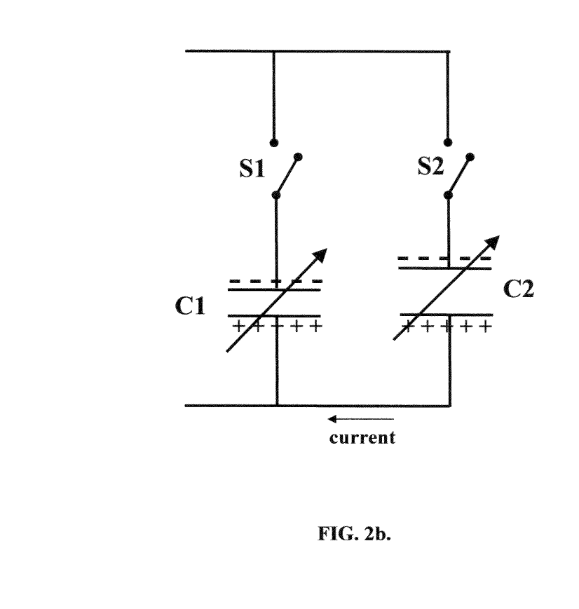

The second embodiment in the present invention is illustrated by FIG. 2a, which shows the apparatus having a pair of variable capacitors (parallel plates type), C1 and C2. The C1 and C2, each has a fixed plate, 100 and 110, and a moving plate, 200 and 210, respectively. These plates can be made of metal, semiconductor or insulator. They have aligned metallic films, 120, 130, 140, and 150, which may be different for the moving plate and fixed plate. The moving plates, 200 and 210, are attached to the fixture, 300, and therefore move along with the motion of 300. The circuit connected to both C1 and C2 are controlled with two independent switchers, S1 and S2, respectively. The variable capacitor operation can be illustrated by the following example. When the variable capacitor C1 is at its initial stage, it has the narrowest gap and the switch S1 closes, therefore a current starts to charge C1. Meanwhile, C2 has the widest gap and S2 is closed to transfer energy from C2 to the circuit. Then the fixture 300 moves by external work, which causes the gap for C1 to widen and the energy in C1 increases accordingly, while the gap of C2 is contracting. When 300 reaches the maximum length, C1 has the widest gap and then S1 opens to transfer the energy from C1 to the circuit. Meanwhile, C2 is at its initial stage with the narrowest gap and then S2 closes for charging. Afterward, both S1 and S2 are open for repeating the same energy generation circle. FIG. 2b shows the circuit diagram.

The third embodiment of the present invention can be discussed by referring to FIG. 3, which shows the apparatus of the solar energy conversion system. This conversion system uses solar energy and cooling media such as running water or cold air to move the plates of the pair of capacitors back forward. The solar energy is concentrated by a solar reflection trough, 600, which focuses the solar energy to the thermal collector, 500. The thermal collector 500 is fixed at one end by 520 and flexible at the other end with supporter 530. The fixtures 400 is fixed on the flexible end of the collector 500 and connected to the fixture 300. The variable plates, 200 and 210, are fixed on the fixture 300. The stationed plates 100 and 110 are fixed on the base support 240. When the thermal collector 500 has thermal motion—expansion or contraction, the fixtures 400, 300 and the variable plates 200 and 210 move along accordingly. The thermal collector 500 is made of a material with a large thermal expansion coefficient. The fixtures 400, 300 and support 240 may be made of different materials. However the material(s) must have a very small thermal expansion coefficients compared to that of 500, <10% of 500. The axle 510 can be made of different materials than that of the thermal collector 500, but it has to be of material of thermal insulator. The electric conductive films 110, 120, 130, and 140 can be the same or different materials but must have robust conductivity. The thermal collector 500 has two stages, the high temperature stage collects solar energy to heat and the low temperature stage flows cooling media through to cool. The temperature of the thermal collector 500 is controlled by applied energy either the focused solar energy or the cooling media. When the thermal collector 500 becomes hot due to the solar energy collection and no coolant media flow, it elongates and the fixtures 300 and 400 are droved to the right (see FIG. 3). Therefore, C1 has an increasing gap and C2 has a decreasing gap and the energy stored in C1 increases accordingly. When the thermal collector 500 is cooled down, it contracts and the fixtures 300 and 400 move to the left, (see FIG. 3). Then the thermal collector 500 has the shortest length and the variable capacitor C1 is at its initial stage with the narrowest gap and the variable capacitor C2 is at its final stage with the widest gap. The electric circuit connected to C1 and C2 will be either open or closed depending on C1 and C2's positions. The capacitors, C1 or C2, will be charged if it is at the initial stage (narrowest gap) with a closed switch-circuit. The capacitors, C1 or C2, will deliver the stored energy to the circuit if it is at the final stage (widest gap) with a closed switch. One of the two capacitors will always generate energy during the thermal collector 500 expansion (temperature increasing) and the other will always generate energy during the thermal collector 500 contraction (temperature decreasing). During the motion of the thermal collector 500 and therefore the movable plates of C1 and C2, the switches S1 or S2 always open to keep C1 and C2 electrically isolated from each other as well as from the circuit. The repeating frequency of the same energy generation circle depends on the heating and cooling power applied on to the thermal collector 500. There may be multiple pairs of variable capacitors connected onto the fixture 300. There may be multiple fixtures, like 300, connected to the thermal collector 500.

The fourth embodiment of the present invention can be generally used for any thermal sources by directly connecting them to the thermal collector 500. FIG. 4 shows a schematic setup of the apparatus. The heat source and the cooling media are directly connected to the axle 710 and then the thermal collector 500. A valve 720 is used to control the selection of heating or cooling. The valve 720 can be electrically controlled by a controller to synchronize the media selection according to the variable capacitors' actions. Thermal shield 700 covers the thermal collector 500 to reduce the possible thermal exchanges due to radiation as well as thermal contact. Otherwise, this system applies the same operation principle and sequence as for the previously discussed embodiments. For different thermal sources, the thermal collector 500 may have a different maximum temperature and therefore its maximum expansion will be different from that for the solar energy set in the third embodiment. In order to maintain the similar energy generation of the variable capacitors, the ratio of d_{f}/d₀ of the variable capacitor stays the same. When the heating source heats the thermal collector 500 to a higher temperature than the hottest temperature from solar energy conversion, the total length of the thermal collector 500 has to be reduced to compensate for the expansion of the thermal collector 500. When the heating source makes the thermal collector 500 less hot as what from solar energy conversion, the total length of the thermal collector 500 has to be increased to compensate for the short expansion of the thermal collector 500. There may be multiple pairs of variable capacitors connected onto the fixture 300. There may be multiple fixtures, like 300, connected to the thermal collector 500.

To meet the circuit or grid condition or requirement, the multiple variable capacitors can be electrically connected in different ways, series or parallel or mixed series and parallel. There will be a switch for each individual capacitors so that it can be connected or disconnected from the rest of the electric circuit. When the energy output from the energy converter of the present invention matches the condition of the connected grid, the circuit of the present invention will directly deliver the electricity to the grid.

The present invention has been discussed in its first, second, third and fourth embodiments. These embodiments can be used as a combination of multiple variable capacitors and they can have different setup combinations and/or different operational sequences.

Although the description above contains many specifications, these should not be construed as limiting the scope of the present invention but as merely providing illustrations of some of the presently preferred embodiments of the present invention.

Therefore the scope of the present invention should be determined by the claims and their legal equivalents, rather than by the examples given.

What the claims are:

1. An apparatus for solar energy conversion, comprising:
a parabolic trough to concentrate the solar energy;
a thermal collection system for collecting the said thermal energy from the said parabolic though;
a variable capacitor with at least one plate movable
a fixture connecting the said thermal collector system to the said movable plate of said variable capacitor;
a switching means

2. An apparatus according to claim 1, wherein said parabolic trough includes:
a supporter of the said trough;
the said parabolic trough may have different coatings on its surface in order to have the maximum solar energy concentration efficiency;
a possible tracking system to have the most solar energy at any moment.

3. An apparatus according to claim 1, wherein the said thermal collection system includes:
a thermal collector;
a connection of a cooling media supplier to the said thermal collector;
a control of the cooling media flow,
a support of the fixed end of the said thermal collector;
a support of the moving end of the said thermal collector.

4. An apparatus according to claim 1, wherein the fixture includes:
a bar on which the said moving plate of said variable capacitor is mounted on;
a beam to link the said bar to the said thermal collector.

5. An apparatus according to claim 1, wherein, the variable capacitor includes:
a fixed plate;
a movable plate.

6. An apparatus according to claim 1, wherein, the said switching means has disables and enables a switch adjacent to said variable capacitor.

7. An apparatus according to claim 1, wherein the said switching means turns on and off the cooling source and the solar focus, according to the stage of said variable capacitor.

8. An apparatus according to claim 4, wherein, the said bar is made of aluminum or copper or other metals and their alloys have a large thermal expansion coefficient.

9. An apparatus according to claim 4, wherein, the said beam is made of ceramic or glass or plastic materials with a small thermal expansion coefficient.

10. An apparatus according to claim 5, wherein, the said variable capacitor has conductive film on both plates.

11. An apparatus according to claim 5, wherein, the said capacitor gap may be filled by different gas instead of air.

12. An apparatus according to claim 10, wherein, the said capacitor may have a dielectrical material coating atop of said metallic films.

13. An apparatus according to claim 10, wherein, the said capacitor may have different conductive films for the fixed plate and the moving plate.

14. An apparatus according to claim 11, wherein the said capacitor may have different dielectric coatings for the fixed plate and the moving plate.

15. A method of directly converting solar energy to electricity, comprising the following steps:
a variable capacitor set at its initial stage at its narrowest gap;
said variable capacitor charging with original electric energy by closing the electric circuit that said variable capacitor connects to;
opening said electric circuit;
focusing the solar energy on the parabolic trough to heat the thermal collector;
said thermal collector expanding when heating;
the movable plate of said variable capacitor moves with said thermal collector, expanding due to said movable plate being mechanically fixed onto said thermal collector;
when said thermal collector reaches the maximum expansion, said variable capacitor widens to the maximum gap, therefore the largest amount of additional electric energy;
closing said electric circuit to transfer the total electric energy, said original electric energy combined with said additional electric energy, from said variable capacitor into the circuit;
opening said electric circuit
cooling down said thermal collector by connecting to a cooling source connected to said thermal collector and by turning said thermal collector off the focus point of said parabolic trough;
said variable capacitor resets to its initial stage, contracting to its narrowest gap.

16. A method according to claim 15, wherein said heating raises the temperature to the order of 200 C.

17. A method according to claim 15, wherein said thermal collector expansion is in the range of at least equal to the narrowest gap.

18. A method according to claim 15, wherein said variable capacitor has the capacitance of a micro Farad order at said initial stage.

19. A method according to claim 15, wherein said variable capacitor has the voltage of several volts to hundred kilo volts at said initial stage.

20. An apparatus for solar energy conversion, comprising:
a parabolic trough to concentrate the solar energy;
a thermal collection system for collecting the said thermal energy from the said parabolic though;
pairs of variable capacitors with at least one movable plate for each capacitor;
fixtures connecting the said thermal collector system to the said movable plates of said variable capacitors;
a switching means

21. An apparatus according to claim 20, wherein said pair of variable capacitors includes:
a fixed plate of any shape for each said capacitor;
a movable plate of any shape for each said capacitor;
said pair variable capacitor being arranged in such a way that when widening its gap, the other decreases, vise versa.

22. An apparatus according to claim 20, wherein the said switching means has one switch for each said variable capacitor.

23. An apparatus according to claim 20, comprising of multiple said variable capacitors operated with the electric circuit connected series to increase the output energy voltages.

24. An apparatus according to claim 20, comprising of multiple said variable capacitors operated with the electric circuit connected parallel to increase the output energy current.

25. An apparatus according to claim 20, comprising of multiple said pairs of said variable capacitors operated with the electric circuit connected, mixed with series and parallel, to generate the output energy with additional voltage and additional current.

26. An apparatus according to claim 20, comprising of multiple said fixtures that each connect to multiple said pairs of said variable capacitors.

27. An apparatus according to claim 20, comprising of multiple said fixtures that connect to multiple said pairs of said variable capacitors that have the electric circuit connected, mixed with series and parallel connections, to generate the output energy with additional voltage and additional current.

28. A method of converting solar energy to electricity directly, comprising the following steps:
when one variable capacitor is at its initial stage with the narrowest gap, another variable capacitor is at its final stage with the widest gap;
after the first said variable capacitor charges, another said variable capacitor delivers its total electric energy, the original electric energy combined with the additional electric energy, into the connected circuit;
said switches for both said variable capacitors open to produce an open electric circuit;
focusing the solar energy on the parabolic trough to heat the thermal collector which expands when heated;
when the gap of the first said variable capacitor becomes the widest gap and another said variable capacitor returns to its initial stage;
closing said switch for the first said capacitor to transfer said total electric energy into the connected circuit;
closing said switch for another said capacitor to charge it with said original electric energy;
opening said switches for both said capacitors to make an open electric circuit;
cooling said thermal collector by connecting it to a cooling source connected to said thermal collector and by turning said thermal collector off focus from said parabolic trough;
said thermal collector reaches its initial length when the temperature rests at its initial temperature. The circle is ready to repeat.
